(19) United States
(12) Patent Application Publication
(10) Pub. No.: US 2022/0068588 A1
(43) Pub. Date: Mar. 3, 2022

(54) ION IMPLANTER AND ION SELECTION METHOD

(71) Applicant: SONY SEMICONDUCTOR SOLUTIONS CORPORATION, KANAGAWA (JP)

(72) Inventor: HISAHIRO ANSAI, TOKYO (US)

(21) Appl. No.: 17/310,545

(22) PCT Filed: Jan. 27, 2020
(86) PCT No.: PCT/JP2020/002673

§ 371 Date: Aug. 10, 2021

(30) Foreign Application Priority Data
Feb. 18, 2019 (JP) 2019-026727

(51) Int. Cl. H01J 37/08; H01J 37/317; H01J 37/147; H01J 37/05

(52) U.S. Cl. CPC H01J 37/08; H01J 37/3171; H01L 21/26513; H01J 37/05; H01J 2237/057; H01J 37/1472

(57) ABSTRACT

An ion implanter according to an embodiment of the present disclosure includes: an ion source that includes a plurality of kinds of ions; an extraction electrode that extracts the plurality of kinds of ions from the ion source and generates an ion beam; an ion beam transport tube that transports the ion beam to an object to be irradiated with the ion beam; and an interaction section that is disposed inside the ion beam transport tube, extends substantially parallel to an extending direction of the ion beam transport tube, and is fixed at a predetermined electric potential.

### TECHNICAL FIELD

The present disclosure related to an ion implanter and an ion selection method.

### BACKGROUND ART

An ion implanter is known, which selects ions on the basis of a difference in momentum or energy of ions by providing the ion implanter with a magnetic field filter or an electric field filter on a trajectory of an ion beam (e.g., see PTL 1).

### CITATION LIST

### Patent Literature

PTL 1: Japanese Unexamined Patent Application Publication No. 2014-229599

### SUMMARY OF THE INVENTION

In such an ion implanter, it is desired to improve performance of separating impurity ions.

It is desirable to provide an ion implanter and an ion selection method that are able to improve the performance of separating impurity ions.

An ion implanter according to an embodiment of the present disclosure includes an ion source, an extraction electrode, an ion beam transport tube, and an interaction section. The ion source includes a plurality of kinds of ions. The extraction electrode extracts the plurality of kinds of ions from the ion source and generates an ion beam. The ion beam transport tube transports the ion beam to an object to be irradiated with the ion beam. The interaction section is disposed inside the ion beam transport tube, extends substantially parallel to an extending direction of the ion beam transport tube, and is fixed at a predetermined electric potential.

An ion selection method according to an embodiment of the present disclosure includes: generating an ion beam including a plurality of kinds of ions; and changing a trajectory of the ion beam by an interaction between an interaction section and the ion beam, and selecting a desired ion out of the plurality of kinds of ions. Here, the interaction section is disposed inside an ion beam transport tube that transports the ion beam to an object to be irradiated with the ion beam, extends substantially parallel to an extending direction of the ion beam transport tube, and is fixed at a predetermined electric potential.

According to the ion implanter and the ion selection method according to an embodiment of the present disclosure, the trajectory of the ion beam is changed by the interaction between the interaction section and the ion beam, and the desired ion is selected out of the plurality of kinds of ions.

Here, the desired ion is an ion to be implanted by the ion implanter, and is hereinafter referred to as “desired ion”. Ions other than the desired ion out of the plurality of ions are unnecessary components that become impurities with respect to the “desired ion” to be implanted, and are hereinafter each referred to as “unnecessary ion”.

### BRIEF DESCRIPTION OF DRAWINGS

FIG. 1A is a diagram illustrating an example of a schematic configuration of an ion implanter according to an embodiment of the disclosure.

FIG. 1B is a diagram illustrating an example of a cross-sectional configuration taken along a line I-I′ of the ion implanter illustrated in FIG. 1.

FIG. 2 is a flowchart describing an ion selection method according to an embodiment of the disclosure.

FIG. 3 is a diagram describing a principle of the ion selection method (an interaction between stationary ions and an interaction electrode) according to an embodiment of the disclosure.

FIG. 4A is a diagram illustrating an example of a drop time with respect to a distance between an ion and the interaction electrode in the ion selection method according to an embodiment of the present disclosure.

FIG. 4B is a diagram illustrating an example of a horizontal distance until a drop with respect to the distance between the ion and the interaction electrode in the ion selection method according to an embodiment of the present disclosure.

FIG. 5 is a diagram describing a principle of the ion selection method (an interaction between moving ions and the interaction electrode) according to an embodiment of the disclosure.

FIG. 6 is a diagram illustrating an example of a configuration of a main part of the ion implanter illustrated in FIG. 1A.

FIG. 7 is a diagram illustrating a schematic configuration of an ion implanter according to a reference embodiment.

FIG. 8 is a diagram illustrating a portion of a trajectory of an ion beam of the ion implanter illustrated in FIG. 7.

FIG. 9A is a diagram illustrating an example of a schematic configuration of an ion implanter according to a modification example A.

FIG. 9B is a diagram illustrating an example of a configuration of a main part of the ion implanter illustrated in FIG. 9A.

FIG. 10 is a diagram illustrating an example of a schematic configuration of a main part of an ion implanter according to a modification example B.

FIG. 11 is a diagram illustrating an example of a schematic configuration of a main part of an ion implanter according to a modification example C.

FIG. 12 is a diagram illustrating an example of a schematic configuration of a main part of an ion implanter according to a modification example D.

FIG. 13 is a diagram illustrating an example of a schematic configuration of a main part of an ion implanter according to a modification example E.

FIG. 14 is a diagram illustrating an example of a schematic configuration of a main part of an ion implanter according to a modification example F.

FIG. 15 is a diagram illustrating an example of a schematic configuration of a main part of an ion implanter according to a modification example G.

FIG. 16A is a diagram illustrating an example of a schematic configuration of a main part of an ion implanter according to a modification example H.

FIG. 16B is a diagram illustrating an ion beam of the ion implanter illustrated in FIG. 16A.

### MODES FOR CARRYING OUT THE INVENTION

In the following, some embodiments of the present disclosure are described in detail with reference to the drawings. It is to be noted that description is given in the following order.

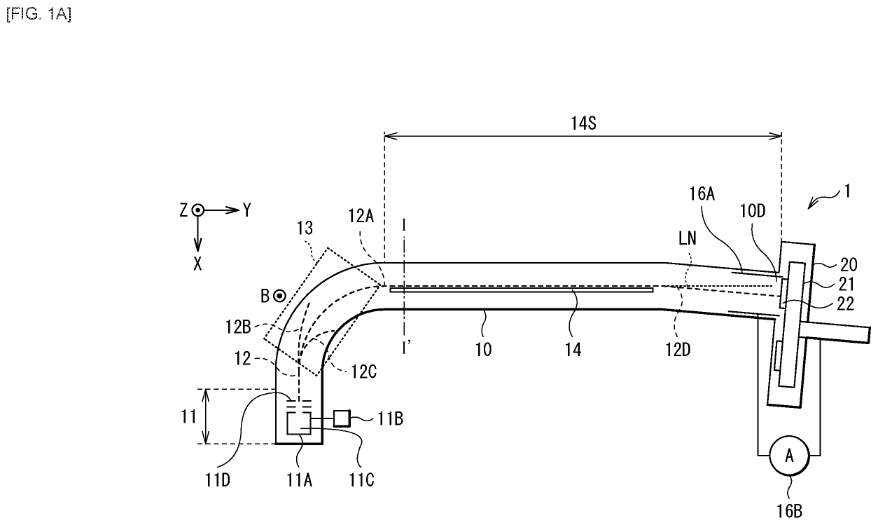

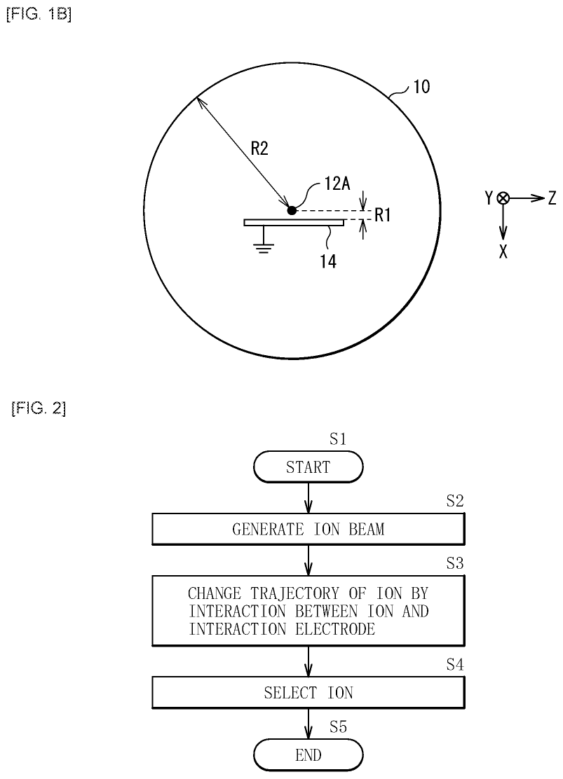

### 1. Embodiment . . . FIGS. 1 to 6

An example in which an interaction electrode is provided inside an ion beam transport tube

### 2. Modification Examples

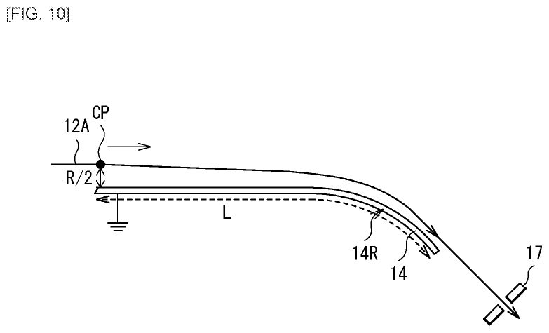

Modification Example A: An example in which a slit is provided in a trajectory of an ion beam . . . FIGS. 9A and 9B

Modification Example B: An example in which a surface of the interaction electrode is curved . . . FIG. 10

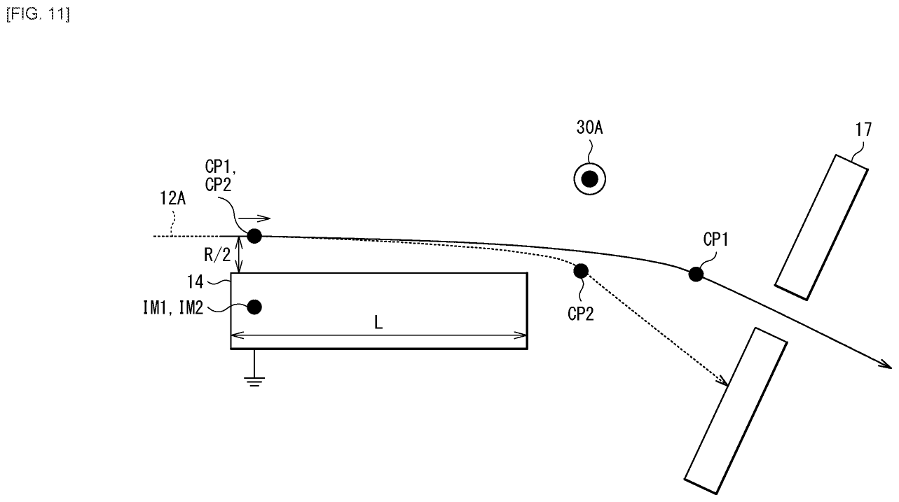

Modification Example C: An example in which a magnetic field for adjusting the trajectory of the ion beam is provided . . . FIG. 11

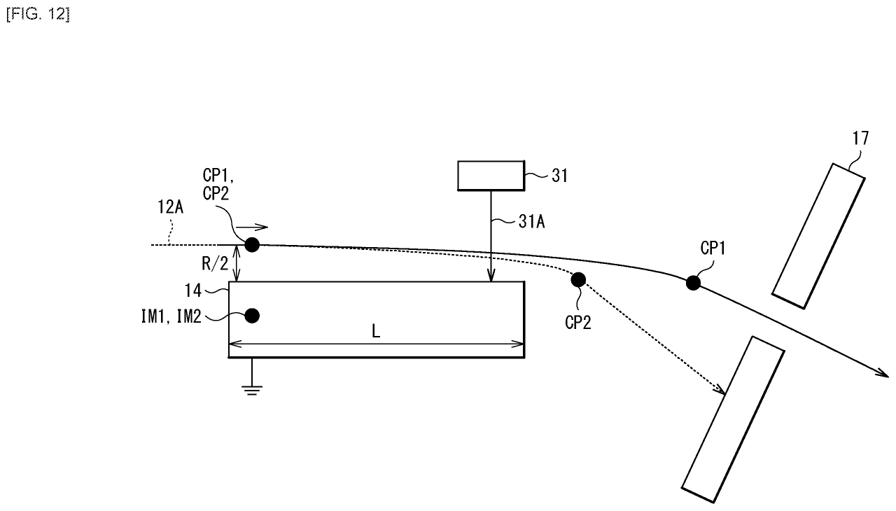

Modification Example D: An example in which an electric field for adjusting the trajectory of the ion beam is provided . . . FIG. 12

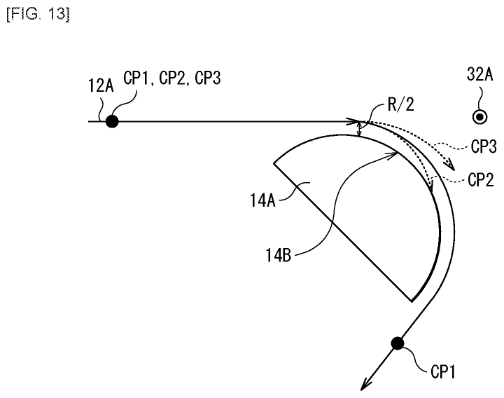

Modification Example E: An example in which the surface of the interaction electrode is curved . . . FIG. 13

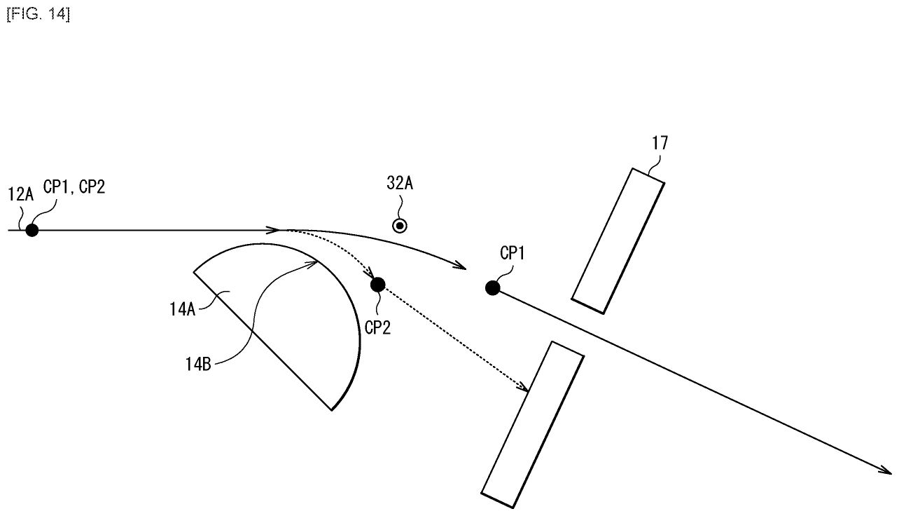

Modification Example F: An example in which the surface of the interaction electrode is curved and the magnetic field for adjusting the trajectory of the ion beam is provided . . . FIG. 14

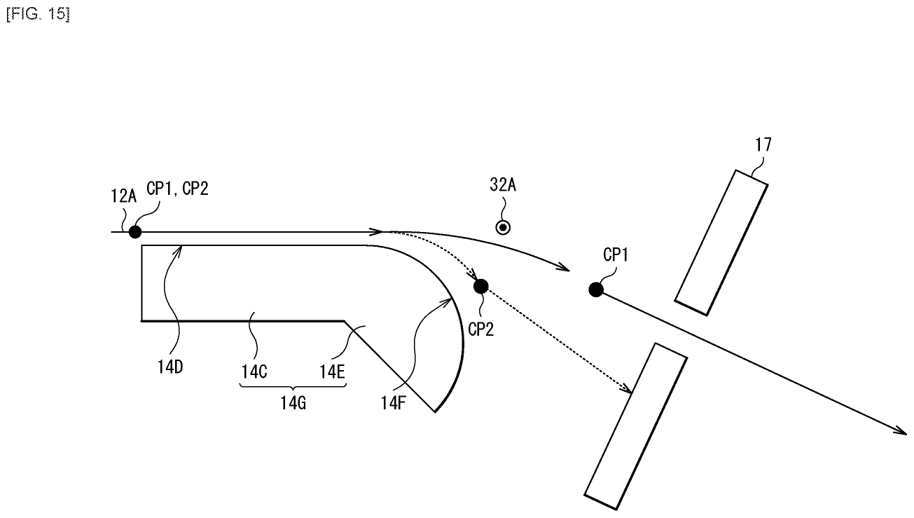

Modification Example G: An example in which a portion of the surface of the interaction electrode is flat, and other portion of the surface of the interaction electrode is curved . . . FIG. 15

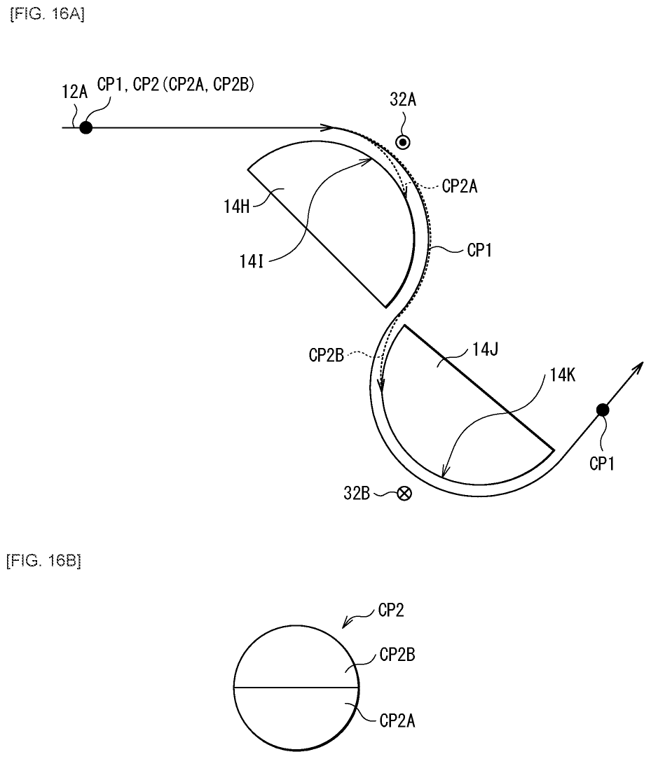

Modification Example H: An example in which multiple interaction electrodes are provided . . . FIGS. 16A and 16B

### 1. Embodiment

### Configuration Example

FIG. 1A is a diagram illustrating an example of a schematic configuration of an ion implanter 1 according to an embodiment of the disclosure. FIG. 1B is a diagram illustrating an example of a cross-sectional configuration taken along a line I-I′ of the ion implanter 1 illustrated in FIG. 1A.

The ion implanter 1 includes an ion source 11C, an extraction electrode 11D, an ion beam transport tube 10, and an interaction electrode 14. The ion beam transport tube 10 transports an ion beam to a wafer 22. The ion beam transport tube 10 includes, for example, an ion beam generator 11, an ion beam deflector 13, and an ion selector 14S, which are disposed in this order from one end toward the other end. The ion beam transport tube 10 corresponds to a specific example of an “ion beam transport tube” of the present disclosure. The ion beam transport tube 10 includes, for example, an extension portion extending in an X-axis direction, an extension portion extending in a Y-axis direction, and a bent portion coupling the extension portions. The wafer 22 corresponds to a specific example of an “object to be irradiated with the ion beam” of the present disclosure. The ion source 11C and the extraction electrode 11D are disposed in the ion beam generator 11, and the interaction electrode 14 is disposed in the ion selector 14S. At the other end of the ion beam transport tube 10, a wafer processing chamber 20 is provided, for example, and the wafer 22 is disposed in the wafer processing chamber 20.

The ion beam generator 11 is a part that generates an ion beam, and is provided in the extension portion extending in the X-axis direction in FIG. 1A, for example. The ion beam generator 11 has an arc chamber 11A, a gas source 11B, the ion source 11C, and the extraction electrode 11D disposed therein. The ion source 11C corresponds to a specific example of an “ion source” according to the present disclosure. The extraction electrode 11D corresponds to a specific example of an “extraction electrode” according to the present disclosure.

The arc chamber 11A is for converting a raw material gas to be an ion source into plasma, and an unillustrated source magnet is disposed in a Z-axis direction, for example. Further, an unillustrated filament is provided in the vicinity of the arc chamber 11A. In the ion beam generator 11, for example, the raw material gas is introduced from the gas source 11B to the arc chamber 11A, and while applying a magnetic field by an unillustrated source magnet, a high voltage is applied by the unillustrated filament to the raw material gas. As a result, the source gas is converted into plasma and the ion source 11C is formed.

The ion source 11C generates ions (the desired ions) to be used for ion implantation, and includes a plurality of kinds of ions CP for reasons to be described later. The extraction electrode 11D is for generating an ion beam 12 from the ion source 11C. In the ion beam generator 11, the plurality of kinds of ions CP including the desired ions are extracted from the ion source 11C by applying a predetermined voltage to the extraction electrode 11D, thereby generating the ion beam 12 including the plurality of kinds of ions CP.

The ion beam deflector 13 is for performing filtering in accordance with a magnitude of a mass-to-charge ratio (mass m/charge number q, hereinafter also referred to as “m/q”) of each ion, and selecting the desired ion from the ion beam 12. The ion beam deflector 13 is disposed, for example, between the ion beam generator 11 and the ion selector 14S, and is configured in the bent portion in FIG. 1A, for example. The ion beam deflector 13 corresponds to a specific example of an “ion beam deflector” of the present disclosure. The ion beam deflector 13 includes, for example, a magnetic field filter that applies a magnetic field to an ion beam and an electric field filter that applies an electric field to an ion beam.

The magnetic field filter performs filtering by a difference in momentum of each ion CP, and includes, for example, an analyzer magnet. When a magnetic field is applied to the ion beam 12, a balance between centrifugal force and Lorentz force causes a direction in which the ion beam 12 is transported (a trajectory) to bend. A degree of bending of the trajectory of the ion beam 12 depends on the mass-to-charge ratio m/q of the ion. For this reason, the ion beam deflector 13 including the magnetic field filter adjusts the magnetic field in such a manner that the desired ion, out of the plurality of kinds of ions included in the ion beam 12, passes through the ion beam deflector 13. As a result, for example, an ion having a mass-to-charge ratio m/q greater (heavier) than that of the desired ion becomes an ion beam 12B whose trajectory has a smaller degree of bending, and is removed by colliding with an inner wall surface of the ion beam transport tube 10. An ion having a mass-to-charge ratio m/q smaller (lighter) than that of the desired ion becomes an ion beam 12C whose trajectory has a larger degree of bending, and is removed by colliding with the inner wall surface of the ion beam transport tube 10. As described above, an ion beam 12A including the desired ion is extracted. The selection of the ion CP performed by the magnetic field filter will be described later.

The electric field filter performs filtering by a difference in energy of each ion CP. When an electric field is applied to the ion beam 12, a balance between the centrifugal force and Coulomb force causes a direction in which the ion beam 12 is transported (a trajectory) to bend. At this time, similarly to the above-described magnetic field filter, the electric field is adjusted in such a manner that the desired ion, out of the plurality of kinds of ions included in the ion beam 12, passes through the ion beam deflector 13. As a result, for example, an ion having m/q greater (heavier) than that of the desired ion and an ion having m/q smaller (lighter) than that of the desired ion are removed by colliding with the inner wall surface of the ion beam transport tube 10. As described above, the ion beam 12A including the desired ion is extracted. The selection of the ion CP performed by the electric field filter will be described later.

It is to be noted that, in the ion implanter 1 according to the present embodiment, the ion beam transport tube 10 is bent from the X-axis direction to the Y-axis direction by 90°; however, the present disclosure is not limited thereto. The ion beam transport tube 10 may be bent at an angle other than 90°.

The ion selector 14S further filters the ion beam 12A selected by the ion beam deflector 13 in accordance with a magnitude of mass m/(charge number q)² (hereinafter also referred to as “m/q²”) of each ion CP to select the desired ion. In the ion selector 14S, the unnecessary ion included in the ion beam 12A is further removed, and an ion beam 12D of the desired ion is selected from the ion beam 12A. The ion selector 14S is provided, for example, in an extension portion extending in the Y-axis direction in FIG. 1A. The interaction electrode 14 is disposed in the ion selector 14S. The interaction electrode 14 corresponds to a specific example of an “interaction section” according to the present disclosure.

The interaction electrode 14 changes the trajectory of the ion beam 12A by interaction between the plurality of ions CP included in the ion beam 12A and image charges IM. The interaction electrode 14 includes, for example, a conductor. The interaction electrode 14 is, for example, a plate-shaped member extending in one-axis direction, and is disposed in the ion beam transport tube 10 in such a manner as to extend substantially parallel to an extending direction of the ion beam transport tube 10, for example. A surface of the interaction electrode 14 is preferably flat, but is not limited thereto, and may have a curved surface. Alternatively, it is preferable that the surface of the interaction electrode 14 has a deviation of a distance between the ion beam 12A and the surface of the interaction electrode 14 within a range of ±10 mm to make effects more easily obtainable with the ion implanter 1.

The interaction electrode 14 is fixed to a predetermined electric potential. The predetermined electric potential is, for example, a ground potential. The ion beam 12A in the ion selector 14S is transported in the vicinity of the interaction electrode 14. Specifically, the ion beam 12A is transported at a position where a distance R1 between the ion beam 12A and the interaction electrode 14 is smaller than a distance R2 between the ion beam 12A and a wall surface of the ion beam transport tube 10, as illustrated in FIG. 1B, for example.

It is to be noted that, in FIG. 1A, a virtual trajectory of the ion beam 12A of a case where there is no interaction with the interaction electrode 14 is indicated by a dashed line LN. In practice, the trajectory of the ion beam 12A, after drawing a linear trajectory for a predetermined distance as illustrated in FIG. 1, is bent toward side of the interaction electrode 14 rather than side of the dashed line LN, owing to an influence of the interaction electrode 14. The selection of the ion CP performed by the ion selector 14S will be described later.

The other end of the ion beam transport tube 10 is provided with the wafer processing chamber 20. A base 21 that is able to be driven normally is provided inside the wafer processing chamber 20, and the wafer 22 is held on the base 21. In the wafer processing chamber 20, the wafer 22 is irradiated with the ion beam 12D on the base 21. In order to improve uniformity of the ion beam radiation, the base 21 may be rotationally driven.

The wafer processing chamber 20 is provided with a Faraday cup 16A near the other end (an ion beam outlet 10D) of the ion beam transport tube 10. An ammeter 16B is coupled to the Faraday cup 16A and the base 21. The ammeter 16B measures an amount of a beam current beam used for ion implantation, which makes it possible to control an amount of the ion implantation in accordance with the obtained amount of beam current.

### Ion Selection Method in Ion Selector

Next, an ion selection method in the ion selector 14S will be described. FIG. 2 illustrates a flow of ion selection in the ion selector 14S. First, when the ion selection method is started in the ion implanter 1 (step S1), the ion beam generator 11 generates the ion beam 12 including the plurality of kinds of ions CP, and the ion beam deflector 13 selects an ion on the basis of a charge-to-mass ratio (m/q) and generates the ion beam 12A (step S2). Next, the ion selector 14S selects an ion. In the ion selector 14S, the interaction between the interaction electrode 14 and the ion beam 12A changes the trajectory of the ion beam (step S3). Subsequently, a desired ion is selected from the plurality of kinds of ions CP included in the ion beam 12A (step S4). In this way, the desired ion is selected from the plurality of kinds of ions CP.

Step S3 will be described in detail. In step S3, the interaction between the image charges IM in the interaction electrode 14 with respect to the plurality of kinds of ions CP and the plurality of kinds of ions CP changes the trajectory of the ion beam 12A. The ion beam 12A includes, for example, a first ion CP1 and a second ion CP2 as the plurality of kinds of ions. The first ion CP1 has a first mass m1 and a first charge number q1. The second ion CP2 has a second mass m2 and a second charge number q2. In the ion selector 14S, the interaction between the interaction electrode 14 and the ion beam 12A causes the first trajectory of the first ion CP1 and the second trajectory of the second ion CP2 to differ from each other in accordance with a difference between m1/(q1)² and m2/(q2)². As described above, in the ion selector 14S, the unnecessary ion is removed from the plurality of kinds of ions CP on the basis of mass m/(charge number q)² by the interaction between the interaction electrode 14 and the ion beam 12A, and the desired ion is extracted (selected).

### [Operation]

In the ion implanter 1, the ion beam generator 11 generates the ion beam 12, and the ion beam deflector 13 performs selection of the ion CP based on the mass-to-charge ratio m/q to extract the ion beam 12A including the desired ion. Next, the ion selector 14S performs selection of the ion CP based on mass m/(charge number q)² to further remove the unnecessary ion included in the ion beam 12A, selects the ion beam 12D of the desired ion, and irradiates the wafer with the ion beam 12D. The filtering of the ions CP in the ion beam deflector 13 and the ion selector 14S of the ion implanter 1 according to the present embodiment will be described in detail below.

The ion beam 12 generated by the ion beam generator 11 includes, in addition to the desired ion to be implanted, the unnecessary ion. Examples of the unnecessary ion mixed in the ion beam 12 include gas of the gas source 11B or impurities included therein, a metal element derived from a metal member included in the arc chamber 11A, tungsten to be emitted from the unillustrated filament, and the like. BF₃, B₂F₆, or the like is generally used as an ion source of boron (B). POCl₃, PF₃, PH₃, or the like is used as an ion source of phosphorus (P). AsH₃ or the like is used as an ion source of arsenic (As). In addition to the desired ion (an ion of B, P or As), various ions such as single ions of hydrogen (H), oxygen (O), and fluorine (F) included in the ion sources described above and molecular ions with B, P, and As are released as the unnecessary ions in the arc chamber 11A. Further, iron (Fe), nickel (Ni), chromium (Cr), tungsten (W), molybdenum (Mo), and the like, which form the arc chamber 11A and the unillustrated filament, are partially ionized and released to be the unnecessary ions.

The filtering of the ion CP performed by the ion beam deflector 13 including the magnetic field filter will be described. The ion beam deflector 13 applies a magnetic field of a magnetic flux density B in the Z-axis direction to the ion beam 12 including the plurality of kinds of ions CP generated by the ion beam generator 11. Each ion CP receives the Lorentz force F owing to the magnetic field, and the trajectory is bent. Assuming that a radius of the trajectory is represented by r, a mass of the ion is represented by m, and the charge number is represented by q, the following expression holds. Expression (1) represents energy when an extraction voltage V is applied to the ion CP.

[Math. 1]

E=qV=½mv² (1)

Further, Expression (2) represents the balance between the centrifugal force and the Lorentz force.

$$\begin{matrix}[ Math . 2 ] & \\ m \frac{{v}^{2}}{r} = qvB & ( 2 )\end{matrix}$$

From the above-described Expression (1) and Expression (2), the radius r of the trajectory is represented by Expression (3).

[Math. 3]

r=1/B\sqrt{^{(2Vm)}/q} (3)

The magnetic flux density B and the extraction voltage V are constant; therefore, the radius r of the trajectory is determined on the basis of the mass-to-charge ratio m/q. For example, the ion beam 12B of the unnecessary ion whose mass-to-charge ratio m/q is greater (heavier) than that of the desired ion has an increased radius r of the trajectory, and is removed by colliding with the inner wall surface of the ion beam transport tube 10. For example, the ion beam 12C of the unnecessary ion whose mass-to-charge ratio m/q is smaller (lighter) than that of the desired ion, has a decreased radius r of the trajectory, and is removed by colliding with the inner wall surface of the ion beam transport tube 10. The ion beam deflector 13 is able to select the ion CP on the basis of the mass-to-charge ratio m/q and extract the ion beam 12A including the desired ion.

Considering an electromagnetic field having the magnetic field of the magnetic flux density B and an electric field Ef, an equation of a motion of the ion CP that moves in the electromagnetic field is represented by Expression (4).

$$\begin{matrix}[ Math . 4 ] & \\ F = m \frac{d v}{d t} & ( 4 )\end{matrix}$$

Further, the Lorentz force in the electromagnetic field is represented by Expression (5).

[Math. 5]

F=q(Ef+ν×B) (5)

On the basis of Expression (4) and Expression (5), Expression (6) holds.

$$\begin{matrix}[ Math . 6 ] & \\ \frac{m}{q} \cdot \frac{d v}{d t} = ( E f + v \times B ) & ( 6 )\end{matrix}$$

As is apparent from Expression (6), even in the electromagnetic field in which the magnetic field of the magnetic flux density B and the electric field Ef exist, the ions CP having different mass-to-charge ratios m/q move at different trajectories, in a similar manner as in the case of the magnetic field filter. The ion beams 12B and 12C including unnecessary ions may each be caused to collide with the inner wall surface of the ion beam transport tube 10, or may each be shielded by providing a slit, to cause the ion beam 12A including the desired ion to pass through to be extracted. Thus, in the ion beam deflector 13, it is possible to select the ion CP on the basis of the mass-to-charge ratio m/q, and to extract the ion beam 12A including the desired ion.

Even in a case where the ion beam deflector 13 is the electric field filter which applies the electric field Ef, an equation in which B is 0 (zero) in Expression (6) holds, and the ions CP having different mass-to-charge ratios m/q move at different trajectories. In a similar manner to the above, the ion beam deflector 13 (the electric field filter) is able to select the ion CP on the basis of the mass-to-charge ratio m/q, and to extract the ion beam 12A including the desired ion.

Next, the filtering of the ion CP performed by the ion selector 14S will be described. The ion selector 14S removes the unnecessary ion from the plurality of kinds of ions CP on the basis of mass m/(charge number q)² to select the desired ion, as described above.

As described above, the ion beam deflector 13 performs selection of the ion CP based on the mass-to-charge ratio m/q, and the ion beam 12 generated in the ion beam generator 11 includes, as the unnecessary ion, the ion CP whose mass-to-charge ratio m/q is approximated. For example, in a case where the desired ion is phosphorus (P), examples of ions having a mass-to-charge ratio m/q approximate to that of the P ion (³¹P⁺, hereinafter referred to as P⁺) include a molybdenum (Mo) ion (⁹⁴Mo³⁺, hereinafter referred to as Mo³⁺) and a tungsten (W) ion (¹⁸⁶W⁶⁺, hereinafter referred to as W⁶⁺). Table 1 represents a charge number q, a unified atomic mass unit u, a mass-to-charge ratio u/q, and a difference A (u/q)(%) in the mass-to-charge ratio with respect to phosphorus, of each of the ions CP of P⁺, Mo³⁺, and W⁶⁺.

TABLE 1

| | Charge | Unified atomic | | |
|---|---|---|---|---|
| Element | number q | mass unit u | u/q | Δ (u/q)(%) |
| P | + | 30.973762 | 30.973762 | — |
| Mo | 3+ | 93.905088 | 31.301696 | 1.058748 |
| W | 6+ | 185.954362 | 30.992394 | 0.060153 |

As described in Table 1, the mass-to-charge ratios u/q of P⁺, Mo³⁺, and W⁶⁺ are approximate to each other. In the filtering performed by the ion beam deflector 13, it is difficult to separate P⁺, Mo³⁺, and W⁶⁺ from each other. For example, in the ion beam 12A obtained for a purpose selecting of P⁺, Mo³⁺ and W⁶⁺, which are unnecessary ions, are mixed. Accordingly, in a case where the wafer 22 is irradiated with the ion beam 12A, ions of Mo³⁺ and W⁶⁺ are implanted in addition to P⁺. Such metallic contamination caused by unnecessary ions greatly influences characteristics and a lifetime of a semiconductor device. Therefore, it is desired to improve performance of separating ions in such a manner as to remove the unnecessary ion and select the desired ion.

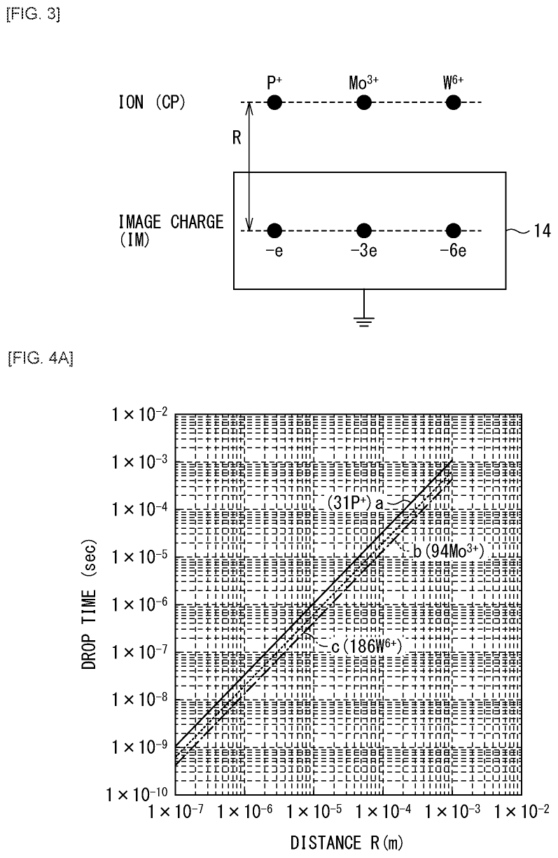

FIG. 3 illustrates a principle of the ion selection method (an interaction between stationary ions and the interaction electrode 14) in the ion selector 14S. In FIG. 3, P⁺ Mo³⁺, and W⁶⁺ are exemplified as three kinds of ions CP mixed in the ion beam 12A. Assume a state in which three kinds of ions CP (P⁺, Mo³⁺, and W⁶⁺) separated by a distance of R/2 from the interaction electrode 14 fixed to a given potential (e.g., a ground potential) are stationary. The equation of the motion of the ion is represented by Expression (4) above. Here, the ion CP interacts with the image charge IM corresponding to each ion CP in the interaction electrode 14. The image charge IM has an opposite polarity to that of the ion CP and has the same charge number. Also, a depth of the image charge IM in the interaction electrode 14 is equal to a distance between the ion CP and the interaction electrode 14. A distance between the ion CP and the image charge IM is R. The ion CP and the image charge IM at positions which are separated away by the distance R interacts with each other by the Coulomb force, and attract each other. The Coulomb force of the ion CP to the image charge IM is represented by Expression (7). In Expression (7), ε represents a dielectric constant.

$$\begin{matrix}[ Math . 7 ] & \\ F = - \frac{{q}^{2}}{4 π ɛ {R}^{2}} & ( 7 )\end{matrix}$$

Expression (8) is derived from Expression (4) and Expression (7).

$$\begin{matrix}[ Math . 8 ] & \\ \frac{m}{{q}^{2}} \frac{d v}{d t} = - \frac{1}{4 π ɛ {R}^{2}} & ( 8 )\end{matrix}$$

As is apparent from Expression (8), in the interaction between the ion CP and the interaction electrode 14, the motion of the ion CP is determined by m/q². That is, the three kinds of ions CP (P⁺, Mo³⁺, W⁶⁺) are similar in the mass-to-charge ratio m/q, but differ in magnitude of m/q², which makes it possible to be separated from each other.

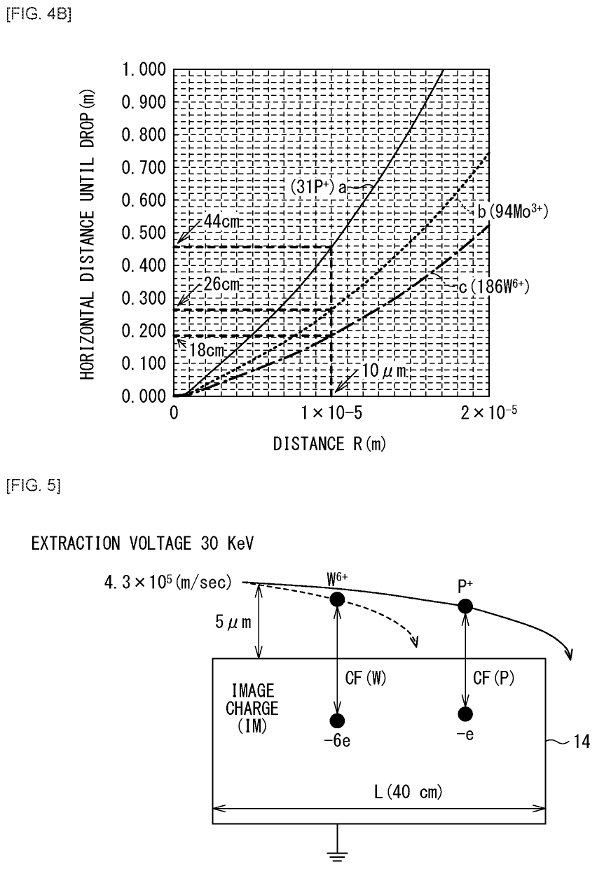

FIG. 4A represents a drop time of the ion CP with respect to the distance between the ion CP and the interaction electrode 14. The drop time is a time taken for each ion CP to reach (drop onto), from a position away from the surface of the interaction electrode 14 by R/2, the surface of the interaction electrode 14 by interacting with the image charge IM which is at a position away from the ion CP by the distance R. In FIG. 4A, the three kinds of ions CP (P⁺, Mo³⁺, and W⁶⁺) are represented by straight lines a, b, and c, respectively. As is apparent from FIG. 4A, the three kinds of ions CP (P⁺, Mo³⁺, W⁶⁺) differ in time taken to be dropped onto the interaction electrode 14.

FIG. 4B illustrates a horizontal distance until a drop with respect to the distance between the ion CP and the interaction electrode 14. In FIG. 4B, the three kinds of ions CP (P⁺, Mo³⁺, and W⁶⁺) are represented by curves d, e, and f, respectively. Here, the three kinds of ions CP (P⁺, Mo³⁺, and W⁶⁺) are extracted at a predetermined extraction voltage. The ion CP is moving substantially parallel to the surface of the interaction electrode 14 upon reaching above the interaction electrode 14, and this direction is referred to as horizontal direction. A velocity v at a time point when the ion CP reaches above the interaction electrode 14 is derived from Expression (1) and is represented by Expression (9).

[Math. 9]

ν²=2qV/m (9)

Expression (9) indicates that ions CP having an equal mass-to-charge ratio m/q also have an equal velocity v.

At the time point of reaching above the interaction electrode 14, the distance between the ion CP and the image charge IM is R, assuming that the distance between the ion CP and the interaction electrode 14 is R/2. Hereafter, the distance between the ion and the interaction electrode 14 or the image charge IM at the time point at which the ion CP reaches above the interaction electrode 14 is also referred to as “initial distance”. While passing above the interaction electrode 14, the ion CP interacts with the image charge IM and gradually drops to the interaction electrode 14.

The horizontal distance until the drop illustrated in FIG. 4B is a distance that the ion CP travels in the horizontal direction until the ion CP drops onto the interaction electrode 14 when the ion CP passes above the interaction electrode 14 as described above. FIG. 4B describes that, in a case where the initial distance between the ion CP and the interaction electrode 14 is 5 μm (the initial distance between the ion CP and the image charge IM is 10 μm), P⁺ travels about 44 cm until it is dropped onto the interaction electrode 14. Further, Mo³⁺ travels about 26 cm until it is dropped onto the interaction electrode 14. Further, W⁶⁺ travels about 18 cm until it is dropped onto the interaction electrode 14. As described above, the horizontal distance until the drop differs depending on the magnitude of m/q² of each ion CP.

Here, if a length L of the interaction electrode 14 in the horizontal direction is less than the horizontal distance until the drop of the desired ion and greater than or equal to the horizontal distance to until the drop of the unnecessary ion, the unnecessary ion collides with the interaction electrode 14 and is removed, and the desired ion passes above the interaction electrode 14.

FIG. 5 illustrates a principle of the ion selection method (an interaction between moving ions and the interaction electrode) in the ion selector 14S. Here, the ion beam 12A including P⁺ and W⁶⁺ is assumed. In a case where an extraction voltage is 30 KeV, the velocity v of the ion beam 12A is 4.3×10⁵ msec. The initial distance R/2 from the ions CP (P⁺ and W⁶⁺) included in the ion beam 12A to the interaction electrode 14 is 5 μm, and the initial distance R from the ions CP (P⁺ and W⁶⁺) to the image charge IM is 10 μm. P⁺ interacts with a—1-valent image charge IM by Coulomb force CF (P). W⁶⁺ interacts with a −6-valent image charge IM by Coulomb force CF (W). In the example illustrated in FIG. 5, the length L of the interaction electrode 14 in the horizontal direction is set to 40 cm, thereby making it possible to cause P⁺ to pass and W⁶⁺ to be removed. In FIG. 5, although Mo³⁺ is not illustrated, it is possible to remove Mo³⁺ in the same manner as W⁶⁺. Alternatively, in a case where an influence of Mo³⁺ is small or the like, the length L of the interaction electrode 14 in the horizontal direction is set to 20 cm, thus, P⁺ may be caused to pass and W⁶⁺ may be removed. Although it is not possible to remove Mo³⁺ in a case where Mo³⁺ is mixed therein, this is applicable to the case where an amount of Mo³⁺ mixed in the ion beam 12A is extremely small.

In addition, it is possible to read from FIG. 4B that, assuming that the horizontal distance until the drop is 0.4 m, the distance R at which P⁺ drops is 9 μm and the distance at which W⁶⁺ drops is 17 μm. Accordingly, for example, in a case where the length of the interaction electrode 14 is 0.4 m, P⁺ passes through the ion selector 14S and W⁶⁺ is removed by the ion selector 14S if spread of a beam of W⁶⁺ is greater than or equal to 9 μm and less than or equal to 17 μm. Further, for example, in a case where the length of the interaction electrode 14 is 1.0 m, phosphate (P⁺) passes through the ion selector 14S and tungsten (W⁶⁺) is removed by the ion selector 14S if the spread of the beam of W⁶⁺ beam is greater than or equal to 17 μm and less than or equal to 30 μm.

Assuming that the length of the interaction electrode 14 in the horizontal direction of is represented by L, a time Tf taken for the ion to pass the interaction electrode 14 is represented by Expression (10).

$$\begin{matrix}[ Math . 10 ] & \\ {T}_{f} = \frac{L}{v} & ( 10 )\end{matrix}$$

Also, assuming that the velocity in a direction toward the interaction electrode 14 at the time point when the ion beam 12A reaches above the interaction electrode 14 is zero, then Expression (11), derived from Expression (8), indicates a time Tc taken for the ion CP to collide with the interaction electrode 14 when the ion CP and the image charge IM interact with each other by the Coulomb force.

$$\begin{matrix}[ Math . 11 ] & \\ T c = \frac{\sqrt{2 {ɛ ( π R )}^{3} m}}{q} & ( 11 )\end{matrix}$$

In the ion implanter 1, the length L of the interaction electrode 14 in the horizontal direction is set in such a manner as to satisfy Expression (12). This allows the desired ion (mass m, charge number q) to pass the interaction electrode 14, but ions heavier than the desired ion {(mass 2m, charge number 2q), (mass 3m, charge number 3q), . . . (mass nm, charge number nq) (where n is an integer greater than or equal to 2)} collide with the interaction electrode 14 and are not able to pass the interaction electrode 14.

$$\begin{matrix}[ Math . 12 ] & \\ \frac{\sqrt{{ɛ ( π R )}^{3} m}}{q} < {T}_{f} = \frac{L}{v} < \frac{\sqrt{2 {ɛ ( π R )}^{3} m}}{q} = T c & ( 12 )\end{matrix}$$

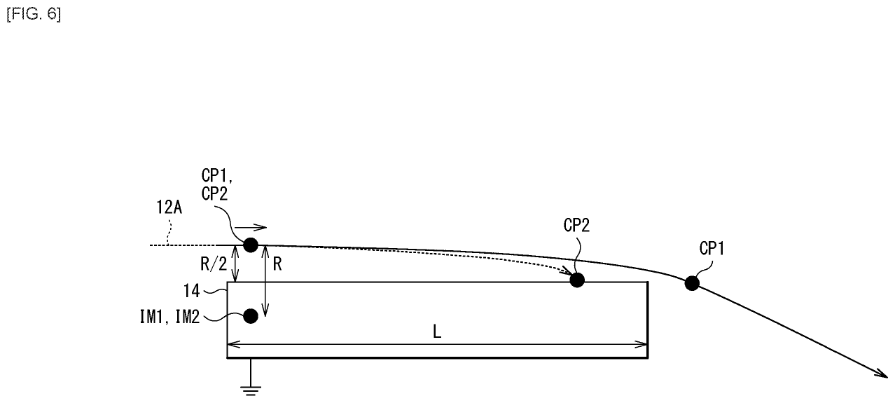

FIG. 6 illustrates an examples of a configuration of a main part (the ion selector) of the ion implanter 1 illustrated in FIG. 1A. FIGS. 3 to 5 describe P⁺, Mo³⁺, and W⁶⁺ as examples of the ions CP; however, the present disclosure is not limited thereto, and are applicable to other ions CP. The interaction electrode 14 illustrated in FIG. 6 is, for example, for interacting with the ion beam 12A including the first ion CP1 and the second ion CP2 whose mass-to-charge ratios m/q approximate to each other, and selecting the desired ion. Here, it is assumed that the first ion CP1 is the desired ion and the second ion CP2 is the unnecessary ion. The first ion CP1 has a first mass m1 and a first charge number q1. The second ion CP2 has a second mass m2 and a second charge number q2.

The first ion CP1 interacts with an image charge IM1 provided inside the interaction electrode 14 when passing above the interaction electrode 14 at the velocity v. Similarly, the second ion CP2 interacts with an image charge IM2 provided inside the interaction electrode 14 when passing above the interaction electrode 14 at the velocity v. The initial distance between the surface of the interaction electrode 14 and the ion beam 12A is R/2, and the surface of the interaction electrode 14 and the trajectory of the ion beam 12A are approximately parallel to each other. Here, in a narrow sense, “approximately parallel” means that the surface of the interaction electrode 14 and the trajectory of the ion beam 12A are parallel to each other within an error range of R/2. The surface of the interaction electrode 14 and the trajectory of the ion beam 12A being approximately parallel to each other in the narrow sense results in an efficient interaction between the ion beam 12A and the interaction electrode 14. In a broad sense, it means that the surface of the interaction electrode 14 and the trajectory of the ion beam 12A are parallel to each other within a range of ±10 mm. The surface of the interaction electrode 14 and the trajectory of the ion beam 12A being approximately parallel to each other in the broad sense results in that the effects are more easily obtainable.

In a case where a distance between the first ion CP1 and the interaction electrode 14 is R/2, the first ion CP1 and the image charge IM1 behave as charged particles that are separated from each other by the distance R. It is also similar for the second ion CP2 and the image charge IM2. The first ion CP1 and the image charge IM1 interact with each other by the Coulomb force, and the first ion CP1 gradually approaches the interaction electrode 14. The second ion CP2 and the image charge IM2 interact with each other by the Coulomb force and the second ion CP2 gradually approaches the interaction electrode 14. In other words, the first ion CP1 and the second ion CP2 drop onto the interaction electrode 14. Here, in the interactions by the Coulomb force, the ion having a larger charge number has a larger interaction with the image charge. Specifically, the interaction electrode 14 causes the a first trajectory of the first ion CP1 and a second trajectory of the second ion CP2 to differ from each other by a difference between m1/(q1)² [symbol] m2/(q2)². The length L of the interaction electrode 14 in an extending direction (the Y-axis direction), the initial distance R/2 from the first ion CP1 and the second ion CP2 to the interaction electrode 14, and the like are adjusted, in such a manner that the second ion CP2 collides with the interaction electrode 14 and the first ion CP1 passes without colliding with the interaction electrode 14. Thus, it is possible to remove the second ion CP2 and extract (select) the first ion CP1, which makes it possible to improve performance of separating (the desired ions and the unnecessary ions) impurity ions, which is to be used for ion implantation.

In the ion beam generator 11, it is preferable that the extraction electrode 11D extract a plurality of kinds of ions at an extraction voltage of, for example, higher than or equal to 10 mV and lower than or equal to 1 MV. The desired ion and the unnecessary ion are extracted at the same extraction voltage. By controlling the extraction voltage, a velocity of each ion is controlled, and it is possible to control duration in which and a distance at which each ion and the interaction electrode 14 interact with each other. It is possible to improve performance of separating impurity ions (desired ions and unnecessary ions), which is to be used for ion implantation.

In the ion selector 14S, the distance between the ion beam 12A and the interaction electrode 14 is preferably, for example, greater than or equal to 0.1 nm and less than or equal to 10 mm. The closer the distance between the ion beam 12A and the interaction electrode 14, the greater the interaction. If the distance is greater than 10 mm, a magnitude of the interaction is not large enough for the ion selection. If the distance is closer than 0.1 nm, it becomes difficult to prevent the desired ion from colliding with the interaction electrode 14.

The length L of the interaction electrode 14 in the extending direction (Y-axis direction) is preferably, for example, greater than or equal to 1 mm and less than or equal to 30 m. The longer the length of the interaction electrode 14, the longer the duration of the interaction, and the higher the accuracy of the ion selection; however, if the length exceeds 30 m, it becomes difficult to be made into an ion implanter. Also, if the length is less than 1 mm, the magnitude of the interaction is not large enough for the ion selection.

The ion beam 12A is preferably transported substantially parallel to the surface of the interaction electrode 14, for example, within an error range of ±10 mm. If the error range exceeds ±10 mm, it becomes difficult to perform stable interaction between the ion CP and the interaction electrode 14 in some cases.

A time taken for the ion beam 12A to pass a part interacting with the interaction electrode 14 (the duration in which the interaction electrode 14 and the ion beam 12A interact with each other) is defined as the time Tf. A time taken for at least one of the plurality of kinds of ions CP to drop onto the interaction electrode 14 while passing the part interacting with the interaction electrode 14 in the trajectory of the ion beam 12A is defined as the time Tc. It is preferable that Tf and Tc satisfy, for example, a relationship of Tf≥0.001Tc. Thus, it is possible to obtain a configuration that is able to perform the ion selection in the ion selector 14S satisfactorily.

In the ion implanter 1, the interaction electrode 14 is placed such that the trajectory of the ion beam 12A travels along the surface of the interaction electrode 14. The interaction electrode 14 has, for example, a planar shape having a constant length L in the horizontal direction as illustrated in FIG. 1A; however, the shape is not limited thereto and may have a curved surface.

### Workings and Effects of Ion Implanter 1

In a process of manufacturing a semiconductor device, a step of the ion implantation is a remarkably important step that influences device characteristics and reliability of the semiconductor. For example, in a silicon semiconductor, in order to form a p-type semiconductor, boron (B) is implanted, and in order to form an n-type semiconductor, a dopant such as phosphorus (P) or arsenic (As) is implanted into a wafer using the ion implanter. The ion implanter 1 is able to adjust freely and markedly highly controllably in such a manner as to obtain desired device characteristics, a depth of implantation with an acceleration energy at which implantation is performed into the wafer and a total implantation amount (dose amount) of ions with an amount of current and a time of irradiation.

Here, in order to describe workings and effects of the ion implanter 1, an ion implanter 100 according to reference embodiment will be described.

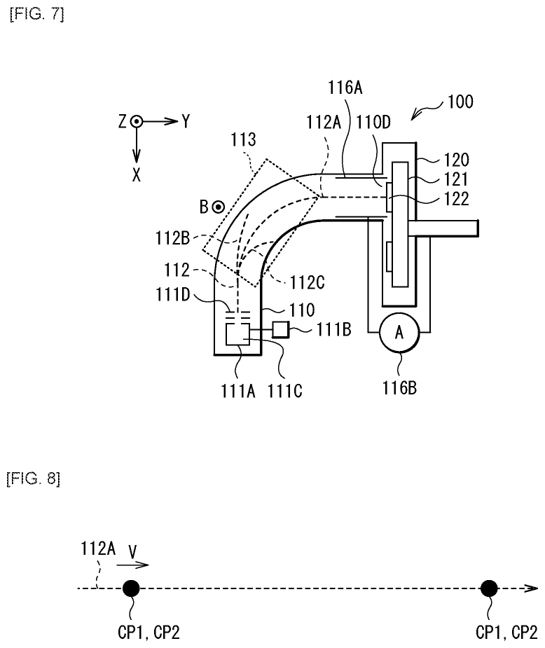

FIG. 7 illustrates a schematic configuration of the ion implanter 100 according to the reference embodiment. The ion implanter 100 generally includes, for example, an ion beam transport tube 110, an arc chamber 111A, a gas source 111B, an ion source 111C, an extraction electrode 111D, an ion beam deflector 113, a Faraday cup 116A, an ammeter 116B, a wafer processing chamber 120, and a base 121. In the ion implanter 100, an ion beam 112 formed by the arc chamber 111A, the gas source 111B, and the like is extracted by the extraction electrode 111D from the ion source 111C. The extracted ion beam 112 is selected on the basis of a difference in momentum or energy of ions while a trajectory is bent by the ion beam deflector 113. That is, an ion beam 112B of ions whose value of m/q is large (heavy) and an ion beam 112C of ions whose value of m/q is small (light) are filtered. An ion beam 112A including the desired ion to be used for the ion implantation is extracted. The extracted ion beam 112A is guided to the wafer processing chamber 120 and applied to the wafer 122.

As described above, it is difficult for the ion beam deflector 113 to separate ions whose mass-to-charge ratios m/q are approximate to each other. Thus, the ion beam 112A includes a plurality of kinds of ions whose mass-to-charge ratios m/q are approximate to each other (e.g., the first ion CP1 and the second ion CP2).

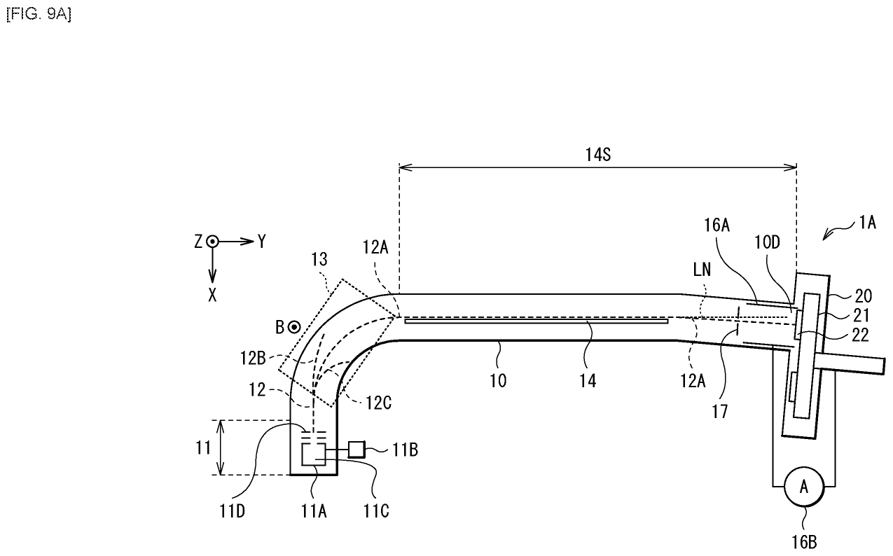

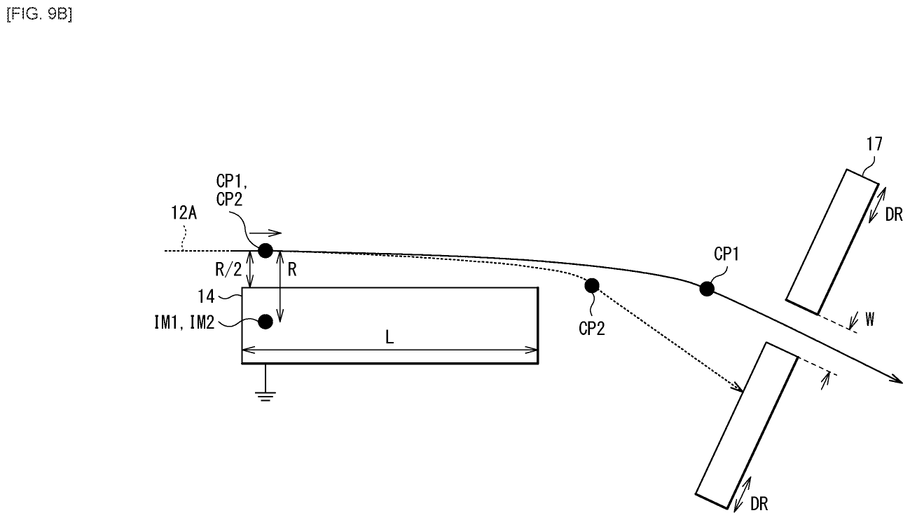

FIG. 8 illustrates a portion of a trajectory of the ion beam after passing through the ion beam deflector 113 of the ion implanter illustrated in FIG. 7. In a case where a mass-to-charge ratio m1/q1 of the first ion CP1 to the mass-to-charge ratio m2/q2 of the second ion CP2 are approximate to each other, the first ion CP1 and the second ion CP2 are transported in the respective trajectories that are similar to each other without being separated after passing through the ion beam deflector 113, and are implanted into the wafer 122. For example, it is extremely difficult to separate ions whose mass-to-charge ratios are different from each other by 1%, no matter how high mass analysis performance of the ion implanter is.

In contrast, the ion implanter 1 according to the present embodiment is provided with, inside the ion beam transport tube 10, the ion selector 14S including the interaction electrode 14 fixed to the predetermined electric potential. In the ion selector 14S, the interaction of the ion beam 12A including the first ion CP1 and the second ion CP2 whose mass-to-charge ratios are approximate to each other versus the interaction electrode 14 causes the first trajectory of the first ion CP1 and the second trajectory of the second ion CP2 to be different from each other. As a result, it is possible to perform selection of the ions whose mass-to-charge ratios are approximate to each other.

As described above, even if the unnecessary ion whose mass-to-charge ratio m/q is approximate to that of the desired ion is mixed in the ion beam including the desired ion to be implanted, the ion implanter 1 according to the present embodiment is able to remove the unnecessary ion. Thus, it is possible to improve performance of separating (the desired ions and the unnecessary ions) impurity ions, which is to be used for ion implantation.

In the process of manufacturing the semiconductor device, the removing of the unnecessary ion at the time of ion implantation makes it possible to improve the device characteristics and the reliability (life) of the semiconductor. For example, in a semiconductor imaging device, a noise such as a white dot is suppressed, and it is possible to improve an image quality. In a power device, a pressure resistance is improved and it is possible to enhance reliability. In a semiconductor memory device, data holding characteristics of stored information are improved, and it is possible to enhance reliability.

### 2. Modification Examples

Modification examples of the ion implanter 1 according to the above-described embodiment will be described below. It is to be noted that in the following modification examples, the same reference numerals are assigned to configurations common to those in the above embodiment.

### Modification Example A

In the ion implanter 1 described above, the unnecessary ion is removed by being collided with the interaction electrode 14, and the desired ion passes above the interaction electrode 14; however, the present disclosure is not limited thereto, and the unnecessary ion and the desired ion both do not collide with the interaction electrode 14, and the unnecessary ion may be removed by using a slit 17.

FIG. 9A illustrates an example of an ion implanter 1A as a modification example A. The ion implanter 1A is provided with the slit 17 at a position at a latter stage of the interaction electrode 14 where the trajectory of the unnecessary ion and the trajectory of the desired ion are sufficiently separated from each other. Except for the above, the configuration is similar to that of the ion implanter 1.

FIG. 9B illustrates an example of a configuration of a main part of the ion implanter illustrated in FIG. 9A. The slit 17 is configured to pass the first ion CP1 and shield the second ion CP2 in a case where the ion beam 12A includes the first ion CP1 and the second ion CP2. For example, in a case where the ion beam 12A includes three kinds of ions CP (P⁺, Mo³⁺, and W⁶⁺), the slit 17 is configured to, for example, pass P⁺ and shield Mo³⁺ and W⁶⁺. For example, the slit 17 is able to be adjusted in position in a predetermined direction DR, and is also able to adjust a slit width W. The slit 17 may be fixed. In particular, in a case where the charge number of the unnecessary ion is less than the charge number of the desired ion, it is not possible to drop the unnecessary ion without dropping the desired ion onto the interaction electrode 14. Even in such a case, the slit 17 is able to remove the unnecessary ion.

A time taken for the ion beam 12A to pass a part interacting with the interaction electrode 14 (the duration in which the interaction electrode 14 and the ion beam 12A interact with each other) is defined as the time Tf. A time taken for at least one of the plurality of kinds of ions CP to drop onto the interaction electrode 14 while passing the part interacting with the interaction electrode 14 in the trajectory of the ion beam 12A is defined as the time Tc. In the ion implanter 1A, Tf and Tc satisfy Expression (13).

$$\begin{matrix}[ Math . 13 ] & \\ {T}_{f} = \frac{L}{v} < \frac{\sqrt{2 {ɛ ( π R )}^{3} m}}{q} = T c & ( 13 )\end{matrix}$$

In Expression (13), in a case where n=3, if L is set to satisfy Expression (13) (L is shortened), a trivalent unnecessary ion also passes without colliding with the interaction electrode 14. Even in this case, the trajectory of the ion changes depending on the charge number by the interaction with the interaction electrode 14, and this makes it possible to extract the desired ion by providing the slit 17.

As illustrated in FIG. 9B, the ion beam 12A includes, for example, the first ion CP1 having the first mass m1 and the first charge number q1, and the second ion CP2 having the second mass m2 and the second charge number q2. The first ion CP1 interacts with the image charge IM1 in the interaction electrode 14 by the Coulomb force, and gradually approaches the interaction electrode 14. The second ion CP2 also interacts with the image charge IM2 in the interaction electrode 14 by the Coulomb force, and gradually approaches the interaction electrode 14. The length L of the interaction electrode 14 in the extending direction (the Y-axis direction) is adjusted to be short to an extent that neither the first ion CP1 nor the second ion CP2 drop onto the interaction electrode 14. The interaction with interaction electrode 14 causes the first trajectory of the first ion CP1 and the second trajectory of the second ion CP2 to be different from each other. A position of the slit 17 is adjusted in such a manner that the first ion CP1 passes and the second ion CP2 does not pass. Thus, it is possible to extract (select) the first ion CP1.

Similarly to the ion implanter 1, even if the unnecessary ion whose mass-to-charge ratio m/q is approximate to that of the desired ion is mixed in the ion beam including the desired ion to be implanted, the ion implanter 1A is able to remove unnecessary ion. Further, the ion implanter 1A is able to reduce the distance R/2 between the ion beam 12A and the interaction electrode 14, and shorten the length L of the interaction electrode 14. As a result, it is possible to achieve miniaturization of the ion implanter.

### Modification Example B

In the above ion implanter 1, the surface of the interaction electrode 14 has a planar shape; however, the present disclosure is not limited thereto, and may have a curved surface.

FIG. 10 illustrates an example of a main part of an ion implanter 1B as a modification example B. The interaction electrode 14 has a curved surface portion 14R. For example, the trajectory of the ion beam 12A is bent toward side of the interaction electrode 14 by the interaction with the interaction electrode 14, and a curvature of the curved surface portion of the interaction electrode 14 is provided to match the trajectory of the ion beam 12A. Except for the above, the configuration is similar to that of the ion implanter 1.

Similarly to the ion implanter 1, even if the unnecessary ion whose mass-to-charge ratio m/q is approximate to that of the desired ion is mixed in the ion beam including the desired ion to be implanted, the ion implanter 1B is able to remove unnecessary ion. Further, in the ion implanter 1B, the surface of the interaction electrode 14 has a shape that matches the trajectory of the ion beam 12A, and it is possible to ensure a distance at which and duration in which the ion beam 12A and the interaction electrode 14 interact with each other. As a result, it is possible to achieve miniaturization of the ion implanter.

### Modification Example C

In the ion implanter 1A, the trajectory of the ion beam 12A is changed by the interaction between the interaction electrode 14 and the ion CP in the ion selector 14S; however, the present disclosure is not limited thereto, and a magnetic field for adjusting the trajectory may be further provided.

FIG. 11 illustrates an example of a main part of an ion implanter 1C as a modification example C. A magnetic field 30A that changes the trajectory in a supplementary manner is provided at a portion of the trajectory of the ion beam 12A. The portion of the trajectory is a part in which the trajectory is changed by the interaction of the first ion CP1 and the second ion CP2 with the interaction electrode 14. Except for the above, the configuration is similar to that of the ion implanter 1A.

Similarly to the ion implanter 1, even if the unnecessary ion whose mass-to-charge ratio m/q is approximate to that of the desired ion is mixed in the ion beam including the desired ion to be implanted, the ion implanter 1C is able to remove unnecessary ion. Further, the ion implanter 1C has the magnetic field 30A for adjusting the trajectory, and the adjustment is easily performed even if the slit 17 is fixed for allowing the desired ion (the first ion CP1) to pass through and preventing the unnecessary ion (the second ion CP2) from passing through. [Modification Example D]

In the ion implanter 1A, the trajectory of the ion beam 12A is changed by the interaction between the interaction electrode 14 and the ion CP in the ion selector 14S; however, the present disclosure is not limited thereto, and an electric field for adjusting the trajectory may be further provided.

FIG. 12 illustrates an example of a main part of an ion implanter 1D as a modification example D. An electric field 31A that changes the trajectory in a supplementary manner is provided at a portion of the trajectory of the ion beam 12A. The portion of the trajectory is a part in which the trajectory is changed by the interaction of the first ion CP1 and the second ion CP2 with the interaction electrode 14. Except for the above, the configuration is similar to that of the ion implanter 1A.

Similarly to the ion implanter 1, even if the unnecessary ion whose mass-to-charge ratio m/q is approximate to that of the desired ion is mixed in the ion beam including the desired ion to be implanted, the ion implanter 1D is able to remove unnecessary ion. Further, in the ion implanter 1D, the electric field 31A for adjusting the trajectory is applied, and the adjustment is easily performed even if the slit 17 is fixed for allowing the desired ion (the first ion CP1) to pass through and preventing the unnecessary ion (the second ion CP2) from passing through.

### Modification Example E

In the above ion implanter 1, the surface of the interaction electrode 14 has a planar shape; however, the present disclosure is not limited thereto, and may have a curved surface.

FIG. 13 illustrates an example of a main part of an ion implanter 1E as a modification example E. An interaction electrode 14A has a curved surface portion 14B. For example, the interaction electrode 14A may be cylindrical or spherical. In the cylindrical or spherical interaction electrode 14A, a surface interacting with the ion beam has the curved surface portion 14B. Inside of the interaction electrode 14 may have a hollow structure. For example, application of a magnetic field 32A to the ion beam 12A causes a traveling direction of the ion beam 12A to be bent at a predetermined curvature. At this time, the magnetic field 32A or the like is adjusted in such a manner that a traveling direction of the desired ion included in the ion beam 12A is substantially parallel to the curved surface portion 14B of the interaction electrode 14A.

As illustrated in FIG. 13, for example, the ion beam 12A includes, for example: the first ion CP1 having the first mass m1 and the first charge number q1; the second ion CP2 having the second mass m2 and the second charge number q2; and a third ion CP3 having a third mass m3 and a third charge number q3. The first ion CP1, the second ion CP2, and the third ion CP3 interact with the interaction electrode 14A as they pass close to the interaction electrode 14A, and the respective trajectories change depending on differences in charge number. For example, the first ion CP1 is the desired ion, and is adjusted to travel on a trajectory that is substantially parallel to the curved surface portion 14B owing to the bending of the traveling direction caused by the magnetic field 32A and the interaction with the interaction electrode 14A. The second ion CP2 whose charge number is larger than that of the first ion CP1 has a traveling direction that is bent by the magnetic field 32A; however, an influence of the interaction with the interaction electrode 14A is larger than that of the first ion CP1, and the second ion CP2 drops onto the interaction electrode 14A. The third ion CP3 whose charge number is smaller than that of the first ion CP1 has a traveling direction that is bent by the magnetic field 32A; however, the influence of the interaction with the interaction electrode 14A is smaller than that of the first ion CP1, and the third ion CP3 moves away from the surface of the interaction electrode 14A. Adjustment is performed in such a manner that the desired ion travels on the trajectory substantially parallel to the curved surface portion 14B using the magnetic field 32A or the like, which makes it possible to remove the second ion CP2 and the third ion CP3 serving as the unnecessary ions and to extract the first ion CP1 serving as the desired ion. Except for the above, the configuration is similar to that of the ion implanter 1.

Similarly to the ion implanter 1, even if the unnecessary ion whose mass-to-charge ratio m/q is approximate to that of the desired ion is mixed in the ion beam including the desired ion to be implanted, the ion implanter 1E is able to remove unnecessary ion. Further, in the ion implanter 1E, a surface of the interaction electrode 14 is curved, and it is possible to achieve space-saving of the interaction electrode 14A. In addition, it is possible to ensure a long distance in which the ion beam 12A and the interaction electrode 14A interact with each other, which makes it possible to secure a large distance R/2 between the ion beam 12A and the interaction electrode 14A.

### Modification Example F

In the ion implanter 1E, the slit is not provided; however, the present disclosure is not limited thereto, and may include the slit 17.

FIG. 14 illustrates an example of a main part of an ion implanter 1F as a modification example F. Application of the magnetic field 32A to the ion beam 12A causes the traveling direction of the ion beam 12A to be bent at a predetermined curvature. A magnetic flux density of the magnetic field 32A to be applied by the ion implanter 1F is lower than that of the magnetic field 32A to be applied by the ion implanter 1E. Thus, the bending is not performed to an extent that the first ion CP1 and the second ion CP2 travel along the curved surface portion 14B. Here, the first ion CP1 and the second ion CP2 differ in magnitude of the interaction with the interaction electrode 14 depending on the difference in the number of charges, and the second ion CP2 travels on a trajectory closer to the interaction electrode 14A compared to the first ion CP1. The slit 17 is placed in such a manner that, among the first ion CP1 and the second ion CP2 having different trajectories, the first ion CP1 passes through the slit 17 and the second ion CP2 does not pass through the slit. Except for the above, the configuration is similar to that of the ion implanter 1E.

Similarly to the ion implanter 1E, even if the unnecessary ion whose mass-to-charge ratio m/q is approximate to that of the desired ion is mixed in the ion beam including the desired ion to be implanted, the ion implanter 1F is able to remove unnecessary ion. Further, in the ion implanter 1F, it is possible to pass the desired ion (the first ion CP1) and not to pass the unnecessary ion (the second ion CP2) by adjusting the magnetic field 32A and adjusting the slit 17.

### Modification Example G

In the ion implanter 1F, the surface of the interaction electrode 14A that interacts with the ion beam 12A is only the curved surface portion; however, the present disclosure is not limited thereto, and may be configured to have a flat surface portion and the curved surface portion.

FIG. 15 illustrates an example of a main part of an ion implanter 1G as a modification example G. An interaction electrode 14G has a first part 14C, the surface of which is a flat surface portion 14D, and a second part 14E, the surface of which is a curved surface portion 14F. The interaction between the ion beam 12A and the interaction electrode 14 takes place in the flat surface portion 14D and in the curved surface portion 14F. Except for the above, the configuration is similar to that of the ion implanter 1F.

Similarly to the ion implanter 1E, even if the unnecessary ion whose mass-to-charge ratio m/q is approximate to that of the desired ion is mixed in the ion beam including the desired ion to be implanted, the ion implanter 1F is able to remove unnecessary ion. The ion beam 12A and the interaction electrode 14G interact with each other in the flat surface portion 14D and the curved surface portion 14F of the interaction electrode 14G, and it is possible to ensure a long distance in which the ion beam 12A and the interaction electrode 14G interact with each other.

### Modification Example H

The ion implanter 1E includes one interaction electrode having the curved surface portion; however, a plurality of interaction electrodes may be provided and the ions may be selected by multiple electrodes.

FIG. 16A illustrates an example of a main part of an ion implanter 1H as a modification example H. The ion implanter 1H includes a first interaction electrode 14H and a second interaction electrode 14J. The first interaction electrode 14H has a curved surface portion 141. The second interaction electrode 14J has a curved surface portion 14K. Here, the ion beam 12A includes the first ion CP1 and the second ion CP2. The first ion CP1 is the desired ion. The second ion CP2 is the unnecessary ion. The second ion CP2 is an ion having a larger charge number as compared to the first ion CP1. The second ion CP2 has a spread in a cross section perpendicular to the traveling direction as illustrated in FIG. 16B. A half of side closer to the first interaction electrode 14H when the ion beam 12 approaches the first interaction electrode 14H is referred to as lower second ion CP2A, and a half of side farther from the first interaction electrode 14H is referred to as upper second ion CP2B.

As illustrated in FIG. 16A, application of the magnetic field 32A to the ion beam 12A causes the traveling direction of the ion beam 12A to be bent at a predetermined curvature. Here, the magnetic field 32A and the like are adjusted in such a manner that the traveling direction of the first ion CP1 included in the ion beam 12A is substantially parallel to the curved surface portion 141 of the first interaction electrode 14H. The lower second ion CP2A of the second ion CP2 on the side closer to the first interaction electrode 14H drops onto the first interaction electrode 14H.

The first ion CP1 that has passed the first interaction electrode 14H approaches the second interaction electrode 14J. The upper second ion CP2B has not dropped onto the first interaction electrode 14H for the half on the farther side of the first interaction electrode 14H, and approaches the second interaction electrode 14J. Here, application of a magnetic field 32B to the first ion CP1 and the upper second ion CP2B causes the traveling directions of the first ion CP1 and the upper second ion CP2B to be bent at predetermined curvatures. Here, the magnetic field 32B and the like are adjusted in such a manner that the traveling direction of the first ion CP1 is substantially parallel to the curved surface portion 14K of the second interaction electrode 14J. The upper second ion CP2B is on the closer side to the second interaction electrode 14J and drops onto the second interaction electrode 14J. A boundary between the lower second ion CP2A and the upper second ion CP2B is not particularly present; however, a configuration may be such that about a half drops onto the first interaction electrode 14H and the remaining half drops onto the second interaction electrode 14J.

Similarly to the ion implanter 1, even if the unnecessary ion whose mass-to-charge ratio m/q is approximate to that of the desired ion is mixed in the ion beam including the desired ion to be implanted, the ion implanter 1H is able to remove the unnecessary ion. Further, even in the case where the unnecessary ion is included in a beam having a spread, it is possible to perform the separation a plurality of times by interaction with the multiple interaction electrodes.

Although the disclosure is described hereinabove with reference to the example embodiment and the modification examples A to H, these embodiment and modification examples are not to be construed as limiting the scope of the disclosure and may be modified in a wide variety of ways.

In the above embodiment and modification examples, the ion implanter including the interaction electrode that includes a conductor has been described; however, the present disclosure is not limited thereto, and instead, it is possible to apply the present disclosure to an ion implanter including an interaction section that includes a dielectric.

Further, the selection of ³¹P⁺, ⁹⁴Mo³⁺, and ¹⁸⁶W⁶⁺ has been described in the embodiment and the modification examples A to H; however, the present disclosure is not limited thereto, and it is possible to apply those to an ion implanter that separates other ions. For example, a configuration may be such that ⁹²Mo³⁺ is selected and removed with respect to ³¹P⁺. Further, a configuration may be such that ⁴⁹Ti⁺ and ⁹⁸Mo²⁺ may be selected and removed with respect to ⁴⁹BF₂⁺.

Further, in the embodiment and the modification examples A to H, the selection of ions performed by the ion beam deflector 13 and the ion selector 14S has been described; however, the present disclosure is not limited thereto, and it is also possible to apply the present disclosure to an ion implanter in which ions are selected only by the ion selector 14S. For example, the present disclosure is able to be applied to a mass analysis mechanism in a mass analyzer for performing unknown element identification.

It should be appreciated that the effects described herein are mere examples. Effects of the example embodiment and the modification examples of the disclosure are not limited to those described herein. The disclosure may further include any effects other than those described herein.

It is to be noted that the present disclosure may have the following configurations. According to the technology having the following configurations, it is possible to remove an unnecessary ion mixed to an ion to be implanted and to improve performance of separating impurity ions.

(1)

An ion implanter including:
an ion source that includes a plurality of kinds of ions;
an extraction electrode that extracts the plurality of kinds of ions from the ion source and generates an ion beam;
an ion beam transport tube that transports the ion beam to an object to be irradiated with the ion beam; and
an interaction section that is disposed inside the ion beam transport tube, extends substantially parallel to an extending direction of the ion beam transport tube, and is fixed at a predetermined electric potential.
   (2)

The ion implanter according to (1), in which the interaction section changes a trajectory of the ion beam by an interaction between: image charges in the interaction section with respect to the plurality of kinds of ions; and the plurality of kinds of ions.

(3)

The ion implanter according to (1) or (2), in which
the ion beam includes a first ion having a first mass m1 and a first charge number q1, and a second ion having a second mass m2 and a second charge number q2, and
the interaction section causes a first trajectory of the first ion and a second trajectory of the second ion to differ from each other in accordance with a difference between m1/(q1)² and m2/(q2)².
   (4)

The ion implanter according to (3), further including
a slit that causes the first ion to pass through and shields the second ion.
   (5)

The ion implanter according to any one of (1) to (4), in which the predetermined electric potential is a ground potential.

(6)

The ion implanter according to any one of (1) to (5), in which
the ion beam transport tube includes an ion beam generator in which the ion source and the extraction electrode are disposed, and an ion selector inside which the interaction section is disposed, and
the ion beam transport tube further includes an ion beam deflector that is provided between the ion beam generator and the ion selector, and that filters the ion beam by a difference in momentum or energy of the plurality of kinds of ions while causing a direction of the ion beam to be changed to a direction of the object to be irradiated with the ion beam.
   (7)

The ion implanter according to any one of (1) to (6), in which the extraction electrode extracts the plurality of kinds of ions at an extraction voltage of higher than or equal to 10 mV and lower than or equal to 1 MV.

(8)

The ion implanter according to any one of (1) to (7), in which a distance between the ion beam and the interaction section is greater than or equal to 0.1 nm and less than or equal to 10 mm.

(9)

The ion implanter according to any one of (1) to (8), in which the predetermined length of the interaction section is greater than or equal to 1 mm and less than or equal to 30 m.

(10)

The ion implanter according to any one of (1) to (9), in which the ion beam is transported substantially parallel to a surface of the interaction section within an error range of ±10 mm.

(11)

The ion implanter according to (2), in which a time Tf and a time Tc satisfy a relationship of Tf≥0.001Tc, where the time Tf represents a time taken for the ion beam to pass a part interacting with the interaction section in the trajectory, and the time Tc represents a time taken for at least one of the plurality of kinds of ions to drop onto the interaction section while passing the part interacting with the interaction section in the trajectory.

(12)

The ion implanter according to any one of (1) to (11), in which a surface, on side of the ion beam, of the interaction section is planar.

(13)

The ion implanter according to any one of (1) to (12), in which a surface, on side of the ion beam, of the interaction section has a curved surface.

(14)

The ion implanter according to any one of (1) to (13), in which the interaction section is cylindrical or spherical.

(15)

The ion implanter according to any one of (1) to (14), in which the interaction section includes a conductor.

(16)

The ion implanter according to any one of (1) to (14), in which the interaction section includes a dielectric.

(17)

An ion selection method including:
generating an ion beam including a plurality of kinds of ions; and
changing a trajectory of the ion beam by an interaction between an interaction section and the ion beam, and selecting a desired ion out of the plurality of kinds of ions, the interaction section being disposed inside an ion beam transport tube that transports the ion beam to an object to be irradiated with the ion beam, extending substantially parallel to an extending direction of the ion beam transport tube, and being fixed at a predetermined electric potential.
   (18)

The ion selection method according to (17), in which a trajectory of the ion beam is changed by an interaction between: image charges in the interaction section with respect to the plurality of kinds of ions; and the plurality of kinds of ions.

(19)

The ion selection method according to (17), in which
the ion beam includes a first ion having a first mass m1 and a first charge number q1, and a second ion having a second mass m2 and a second charge number q2, and
the interaction between the interaction section and the ion beam causes a first trajectory of the first ion and a second trajectory of the second ion to differ from each other in accordance with a difference between m1/(q1)² and m2/(q2)².

This application claims the benefit of Japanese Priority Patent Application JP2019-026727 filed with the Japan Patent Office on Feb. 18, 2019, the entire contents of which are incorporated herein by reference.

It should be understood by those skilled in the art that various modifications, combinations, sub-combinations, and alterations may occur depending on design requirements and other factors insofar as they are within the scope of the appended claims or the equivalents thereof.

1. An ion implanter comprising:
an ion source that includes a plurality of kinds of ions;
an extraction electrode that extracts the plurality of kinds of ions from the ion source and generates an ion beam;
an ion beam transport tube that transports the ion beam to an object to be irradiated with the ion beam; and
an interaction section that is disposed inside the ion beam transport tube, extends substantially parallel to an extending direction of the ion beam transport tube, and is fixed at a predetermined electric potential.

2. The ion implanter according to claim 1, wherein the interaction section changes a trajectory of the ion beam by an interaction between: image charges in the interaction section with respect to the plurality of kinds of ions; and the plurality of kinds of ions.

3. The ion implanter according to claim 1, wherein
the ion beam includes a first ion having a first mass m1 and a first charge number q1, and a second ion having a second mass m2 and a second charge number q2, and
the interaction section causes a first trajectory of the first ion and a second trajectory of the second ion to differ from each other in accordance with a difference between m1/(q1)² and m2/(q2)².

4. The ion implanter according to claim 3, further comprising
a slit that causes the first ion to pass through and shields the second ion.

5. The ion implanter according to claim 1, wherein the predetermined electric potential is a ground potential.

6. The ion implanter according to claim 1, wherein
the ion beam transport tube includes an ion beam generator in which the ion source and the extraction electrode are disposed, and an ion selector inside which the interaction section is disposed, and
the ion beam transport tube further includes an ion beam deflector that is provided between the ion beam generator and the ion selector, and that filters the ion beam by a difference in momentum or energy of the plurality of kinds of ions while causing a direction of the ion beam to be changed to a direction of the object to be irradiated with the ion beam.

7. The ion implanter according to claim 1, wherein the extraction electrode extracts the plurality of kinds of ions at an extraction voltage of higher than or equal to 10 mV and lower than or equal to 1 MV.

8. The ion implanter according to claim 1, wherein a distance between the ion beam and the interaction section is greater than or equal to 0.1 nm and less than or equal to 10 mm.

9. The ion implanter according to claim 1, wherein the predetermined length of the interaction section is greater than or equal to 1 mm and less than or equal to 30 m.

10. The ion implanter according to claim 1, wherein the ion beam is transported substantially parallel to a surface of the interaction section within an error range of ±10 mm.

11. The ion implanter according to claim 2, wherein a time Tf and a time Tc satisfy a relationship of Tf≥0.001Tc, where the time Tf represents a time taken for the ion beam to pass a part interacting with the interaction section in the trajectory, and the time Tc represents a time taken for at least one of the plurality of kinds of ions to drop onto the interaction section while passing the part interacting with the interaction section in the trajectory.

12. The ion implanter according to claim 1, wherein a surface, on side of the ion beam, of the interaction section is planar.

13. The ion implanter according to claim 1, wherein a surface, on side of the ion beam, of the interaction section has a curved surface.

14. The ion implanter according to claim 1, wherein the interaction section is cylindrical or spherical.

15. The ion implanter according to claim 1, wherein the interaction section includes a conductor.

16. The ion implanter according to claim 1, wherein the interaction section includes a dielectric.

17. An ion selection method comprising:
generating an ion beam including a plurality of kinds of ions; and
changing a trajectory of the ion beam by an interaction between an interaction section and the ion beam, and selecting a desired ion out of the plurality of kinds of ions, the interaction section being disposed inside an ion beam transport tube that transports the ion beam to an object to be irradiated with the ion beam, extending substantially parallel to an extending direction of the ion beam transport tube, and being fixed at a predetermined electric potential.

18. The ion selection method according to claim 17, wherein a trajectory of the ion beam is changed by an interaction between: image charges in the interaction section with respect to the plurality of kinds of ions; and the plurality of kinds of ions.

19. The ion selection method according to claim 17, wherein
the ion beam includes a first ion having a first mass m1 and a first charge number q1, and a second ion having a second mass m2 and a second charge number q2, and
the interaction between the interaction section and the ion beam causes a first trajectory of the first ion and a second trajectory of the second ion to differ from each other in accordance with a difference between m1/(q1)² and m2/(q2)².
